(19) United States
(12) Patent Application Publication
(10) Pub. No.: US 2011/0108085 A1
(43) Pub. Date: May 12, 2011

(54) JUNCTION BOX, USES OF A JUNCTION BOX, AND METHODS

(75) Inventor: Michael Quiter, Ebersberg (DE)

(73) Assignees: YAMAICHI ELECTRONICS CO., LTD., Tokyo (JP); YAMAICHI ELECTRONICS DEUTSCHLAND GMBH, Munich (DE)

(21) Appl. No.: 12/991,894

(22) PCT Filed: May 11, 2009
(86) PCT No.: PCT/EP2009/003329

§ 371 Date: Dec. 23, 2010

(30) Foreign Application Priority Data
May 9, 2008 (DE) 10 2008 022 908.3

(51) Int. Cl. H01L 31/048; H05K 5/00; H01R 43/00

(52) U.S. Cl. 136/244; 174/520; 29/825

(57) ABSTRACT

A junction box for a conductor board, in particular for a solar module, including at least one contact device with a conductor terminal element and a contact element, at least one connection cable with at least one electrical conductor, wherein the electrical conductor contacts the conductor terminal element of the at least one contact device, at least one sealing element surrounding an end area of the connection cable, so that the end area is substantially moisture-tight, a housing device, wherein the housing device is designed to be arranged on the conductor board, the housing device surrounds the at least one sealing element in a contact area, and in the contact area.

The invention relates to a junction or connection box, uses of a junction or connection box, and method.

Conventional solar or photovoltaic modules for generating electric energy from sunlight, as an example of a preferred conductor board, comprise one or more single solar or photovoltaic cells. Depending on the desired voltage and/or current to be provided by the solar module, individual solar cells are connected in parallel and/or in series within the module and thus gathered in photovoltaic or solar cell groups. The solar cell groups are integrated in a flat solar module. The electrical terminal elements of the solar cell groups of the solar module are routed to the outside. In case of a partial decrease of the radiation intensity by sunlight onto individual solar cells or solar cell groups, for example by soiling or shading, the following effects may occur among others:

(1) A (constant) decrease of the radiation intensity within the solar cell groups connected together leads to a reduced performance of the respective solar cell group.

(2) If a solar cell within a solar cell group is partially shaded, this shaded solar cell acts as a blocking diode or resistor within the circuit of the solar cell group, which on the one hand may result in the entire solar cell group no longer being able to supply electric energy, and on the other hand in a damage of the shaded solar cell and thus to a permanent breakdown of the solar cell group.

In any case, different voltages may be applied between the routed-out terminals of the solar cell group of a solar module, depending on the radiation intensity onto the individual solar cells. A connection in series of the solar cell groups by corresponding circuiting of the terminals routed to the outside analogously leads to the above-mentioned problems.

In order to avoid the problems related with the differing radiation intensity of the solar cells, conventional so-called bypass diodes are used, which are electrically connected in an anti-parallel manner with respect to the solar cell groups. These bypass diodes have the effect that the current flow through the solar module is led past solar cell groups that only supply low power, i.e. the terminals of this solar cell group of a solar module are short-circuited by the bypass diode and the corresponding cell group is bypassed thereby. Thus, such a solar cell group does no longer contribute to the overall performance of the solar module, but the overall current flow through the solar panel is substantially unobstructed and a damage of individual solar cell is prevented.

Therefore, in addition to the solar module, solar panels usually comprise an electrical junction or connection box with at least two contact devices and at least one bypass diode. The solar cells in a solar module are usually connected to each other by flat, thin conductor bands. These conductor bands are routed out of the solar module and manually contacted with an electrical contact device arranged in the junction box. The junction box of the solar panel therefore usually has a terminal insertion opening on the side facing the solar module, through which opening the conductor bands are routed through, manually bent and connected e.g. to connection terminals. Conventionally, the junction box is subsequently filled with an insulating resin in order to fixedly connect the conductor bands with each other and to insulate them from each other and to close them in a moisture-tight manner from the environment. The solar module provided with the junction box is referred to as photovoltaic or solar panel.

Due to the manual connecting and the filling of the junction box with resin, the assembly of a solar panel is cost and time-intensive. It is therefore an object of the invention to provide an electrical junction or connection box, a use of the junction, a method for producing a junction box, as well as a method for producing a solar panel, which on the one hand reliably protects the electrical contacts from moisture and on the other hand allows for a simple and cost-effective assembly.

The object is solved by the independent claims. Preferred embodiments are subject of the dependent claims.

Junction Box According to One Aspect

One aspect of the present invention relates to a junction or connection box for a circuit or conductor board, in particular for a photovoltaic or solar module, comprising:
at least one contact device with a conductor terminal element and a contact element,
at least one connection cable with at least one electrical conductor, wherein the electrical conductor contacts the conductor terminal element of the at least one contact device,
at least one sealing element surrounding or circumferencing an end area of the connection cable, so that the end area is substantially moisture-tight,
a housing device, wherein
   the housing device is designed to be arranged on the conductor board,
   the housing device surrounds or circumferences the at least one sealing element in a contact area, and in the contact area, the housing device is closely connected with the sealing element such that the contact area is substantially moisture-tight, and wherein
   the housing device has at least one receiving device with at least two openings, wherein in the receiving device, the contact element is arranged such that the contact element is contactable by an electrical terminal element of the conductor board and the contact element is fixable to or on the electrical terminal element by means of at least one fixing element,
at least one housing lid or cover designed to close at least one opening of the receiving device in a substantially moisture-tight manner.

Advantageously, the junction box only has a small number of individual component parts, so that it can be produced in a simple and cost-effective manner and exhibits increased reliability. Further advantageously, due to the close connection of the housing device, the area in which the at least one connection cable projects out of the junction box is closed against moisture in the environment of the junction box in a substantially moisture-tight manner. In other words, advantageously, due to the cable input or output of the junction box, substantially no moisture can enter the junction box.

The conductor terminal element may in particular comprise a soldering spot, a crimping spot and/or a cable mounting, but in particular may as well be an area of a flat conductor.

Further preferably, the sealing element may be an annular, a hose or tube-shaped elastomer, which is pushed onto the end area of the connection cable or is arranged thereon, so that the end area is surrounded by the sealing element. In particular, the sealing element may at first be a substantially liquid sealing element, which is applied to or sprayed onto the end area of the connection cable, is shaped during a hardening or solidifying process, and thereafter forms the sealing element. In the course of the hardening or solidifying process, the sealing element may shrink or remain constant in volume. In particular, in addition to the end area of the connection cable, also further areas may be surrounded by the sealing element, such as at least in some area(s) the electrical conductor of the connection cable, the contact device and/or the conductor terminal element.

As defined by the application, the term “surrounding” a first three-dimensional body by a two-dimensional body is understood such that at least one two-dimensional, planar section exists, so that a closed line exists in this section in the section face, so that all points of the section face of the first body lie within or on the closed line with the section plane, wherein the geometric center of the closed line lies within the closed line.

The term “close connection” between two bodies as defined by the application is understood to be a direct, immediate, mechanical contacting in a contact area or a contact face. In particular, the close connection can take place by shrinking a surrounding or circumferencing body on another surrounding body, so that the surrounding body in the contact area applies a force or mechanical stress to the surrounding body, so that by an elastic or plastic deformation of the two bodies in the contact area, substantially no gap occurs between the two bodies. In particular, the two bodies may be molten together in the contact area. This does not conflict with the fact that a sufficiently small gap may exist between the two bodies, preferably, the distance between the two bodies in the contact area is less than approx. 10 μm, particularly preferably less than 5 μm, and in particular less than 2 μm.

The term “moisture-tight” as defined by the present application is understood to mean a tightness or a barrier against a fluid, in particular water or water vapor. Moisture tightness is achieved when a migration, i.e. the flow or displacement of the moisture due to a partial pressure difference or the pressure difference or the diffusion, is prevented or sufficiently slowed down. Sufficiently slow may in particular mean that the flow rate of the fluid in a body within pores or along channel-shaped or flat preferential flow paths does preferably not exceed a value of approx. 1 mm per year, further preferably 0.1 mm per year, in particular 0.01 mm per year. For electrical devices, such as the junction box according to the invention, moisture tightness means in particular that the specifications of the standard IP67 and/or the standard IEC 61215, paragraph 10.15 are met, that means in particular that upon submerging the junction box in water, the interior of the junction box is electrically insulated from the exterior for at least 2 minutes with a resistance of larger than 400 MΩ.

In other words, a contact area between two bodies, which are in particular closely connected with each other, is moisture-tight exactly when a fluid cannot migrate or migrate only sufficiently slow along the (flat) contact area. That means, if for example a first body with an opening is closed by another second body closing the opening, so that the two bodies mechanically contact each other in a contact area, in particular are in a close connection, then the opening of the body is closed in a moisture-tight manner by the other body or the contact area between the two bodies is moisture-tight if no fluid flows along the contact area or if it flows sufficiently slow, so that the fluid merely enters the contact area but does not penetrate it entirely.

The term “contact” as defined by the present invention in particular includes electrical and/or mechanical contact.

The term “substantially” may describe a slight deviation from a target value, in particular a deviation within the production accuracy and/or within the necessary accuracy, so that an effect as present with the target value is maintained. Thus, the term “substantially” may describe a deviation from a target value or target position, etc., of less than approx. 30%, less than approx. 20%, less than approx. 10%, less than approx. 5%, less than approx. 2%, preferably less than approx. 1%. The term “substantially” comprises the term “identical”, i.e. without a deviation from a target value, a target position, etc.

Preferred Embodiments of the Junction Box

Preferably, the at least one sealing element is a flexible sealing element, and the housing device is a substantially rigid housing device. Alternatively, it is also possible that the sealing element and the housing device are made of substantially identical materials or comprise identical materials.

The terms “flexible” and “rigid” as defined by the application are understood to mean the following mechanical material properties, which may substantially be quantified by the elasticity modulus E and the shear modulus G. Both a flexible and a rigid material may substantially be elastically and plastically deformable. An elastic deformation is understood to be the geometric deformation of a resilient body by an acting force or mechanical stress (force per area), which is substantially fully reversible if the force or mechanical stress does not act on the body any more, so that the body returns to its original shape. In contrast to a body that is rigid relative thereto, or short rigid body, a flexible body distinguishes itself in that the elasticity modulus Ef and/or the shear modulus Gf of the flexible body, i.e. of the flexible sealing element, are smaller than the elasticity modulus Es and/or the shear modulus Gs of the rigid body, i.e. the rigid housing device. In other words, upon application of a force or mechanical stress of the same magnitude, a flexible body (e.g. the sealing element) is geometrically deformed more strongly than a rigid body (e.g. the housing device).

Further preferably, the ratio Es/Ef and/or Gs/Gf is greater than approx. 1.5, particularly preferably greater than approx. 2 or greater than approx. 5, or greater than approx. 10, in particular greater than approx. 50 or greater than approx. 100. Preferably, the shear modulus Gf of the flexible sealing element is less than 10⁹ Nm⁻², further preferably less than 10⁸ Nm⁻², particularly preferably less than 10⁷ Nm⁻², and particularly less than 5×10⁶ Nm⁻². Preferably, the shear modulus Gs of the rigid housing device is greater than 5×10⁶ Nm⁻², further preferably greater than 10⁷ Nm⁻² or greater than 10⁸ Nm⁻², particularly preferably greater than 10⁹ Nm⁻², and in particular greater than 5×10⁹ Nm⁻².

The rigid housing device may in some area(s) e.g. be made of polyamide, in particular polyamide 66 (PA66) or fiberglass-reinforced polyamide with an elasticity modulus of approx. 1 GPa to approx. 11 GPa, in particular approx. 3 GPa or approx. 10 GPa. The melting temperature of the material of the housing device, in particular of the polyamides, may be approx. 250° C. to approx. 265° C.

The flexible sealing element preferably consists at least in some area(s) or fully of a thermoplastic elastomer (TPE) or a thermoplastic vulcanizate (TPV) or a polyphenylene ether (PPE) or a mixture of polyphenylene ether (PPE) and polyethylene (PE) with an elasticity modulus of approx. 2 MPa to approx. 10 MPa, in particular approx. 3 MPa or approx. 4 MPa. Further preferably, the flexible sealing element is made of a polyolefine. Particularly preferably, the flexible sealing element is made of an α-vinyl copolymer, in particular an ethylene propylene copolymer. The temperature range in which the thermoplastic elastomers are plastically deformable or can melt preferably lies below the melting temperature of the material of the housing device (i.e. in particular of polyamides). In particular, the temperature range is approx. 170° C. to approx. 250° C.

Surprisingly, from the preferred choice of material, there advantageously results a connection between' the housing device and the sealing element, in particular between the rigid housing device and the flexible sealing element, which exhibits specially good adhesive and sealing properties, so that the entire junction box exhibits improved sealing properties against moisture or water vapor, and the interior of the junction box is particularly well protected from detrimental environmental influences. In particular, due to the preferred choice of material, the close connection between the rigid housing device and the flexible sealing element is advantageously achievable, so that the contact area is substantially moisture-tight.

Preferably, the junction box comprises at least two contact devices with one short-circuit area each, wherein the short-circuit areas of the contact devices are electrically connected by means of at least one bypass diode.

Further preferably, the short-circuit areas and/or the at least one bypass diode of the contact devices are at least in some area(s) surrounded by the sealing element, preferably surrounded in a moisture-tight manner.

Advantageously, a double sealing of the bypass diode is achieved thereby, on the one hand, by the enclosure in the sealing element and on the other hand, by the housing device.

Further preferably, the junction box comprises at least two connection cables.

Preferably, the sealing element is applied to the connection cable, the conductor terminal element, the short-circuit area and/or the bypass diode substantially in liquid form, and in particular, a close connection with them is created by cooling and/or hardening of the sealing element.

Advantageously, the sealing element is particularly reliably moisture-tightening after cooling or hardening, since in particular the sealing element comes into a close connection with the individual elements, so that in particular the contact areas with the individual elements are individually per se moisture-tight.

Preferably, the flexible sealing element is at least partly molten or fused together with the insulating sheath of the connection cable.

Preferably, the area of the sealing element molten together with the insulating sheath of the connection cable projects from the housing device at least in some area(s), so that the sealing element forms an anti-kink sleeve of the connection cable.

Advantageously, a kinking of the electrical conductor of the connection cable is prevented thereby, since the preferably flexible and resilient sealing element does not fall below a minimum bending radius of the connection cable, whereby the failure probability of the solar panel provided with the junction box is reduced. Further advantageously, the junction box is protected from damage during a movement, in particular a kinking movement. In particular, the sealing element in the embodiment as a flexible sealing element can follow this movement or compensate for this movement. In particular, the contact area between the sealing element and the cable is substantially fully maintained, and in any case, the sealing element remains connected with the connection cable substantially in a moisture-tight manner.

Preferably, the housing device is at least in some area(s) applied to the sealing element and at least in some area(s) to the contact device substantially in liquid form. Particularly preferably, the housing device is fully applied to the sealing element and/or fully applied to the contact device substantially in liquid form. In particular, the application creates a close connection of the housing device with the sealing element and the contact device by cooling and/or hardening of the housing device.

Preferably, the housing device is in one piece. Here, the housing device may be injection-molded and/or cast in one process step.

Preferably, the housing device is at least partially molten or fused together with the sealing element.

Preferably, the housing device is made of a material that is shrinkable more strongly than the material of the sealing element.

The term “shrinkable” as used in this application describes a change of volume, in particular a reduction of volume, of between approx. 0.1% and 5%, preferably between approx. 0.2% and approx. 2%, particularly preferably between approx. 0.3% and approx. 0.7%.

Preferably, the at least one fixing element is arranged on the at least one housing lid. Particularly preferably, the fixing means is connected with the housing lid, i.e. glued, clamped, welded, molten, etc. In particular, the at least one fixing element and the at least one housing lid are formed integrally or in one piece. Here, the fixing element and the housing lid may be injection-molded and/or cast in one process step.

Preferably, the at least one housing lid has at least one locking element.

Preferably, the at least one housing lid comprises a housing lid sealing element. Further preferably, the housing lid sealing element may be an O ring, which is in particular held in a groove of the housing lid. It is also possible that a substantially liquid sealing material is applied to the housing lid in some area(s), wherein the housing lid sealing element is formed or shaped after hardening or solidifying of the sealing material.

Preferably, the at least one fixing element is made of plastic, or plastics, or metal.

Use According to One Aspect

One aspect of the present invention relates to the use of an inventive connection or junction box and a photovoltaic or solar module as the preferred circuit or conductor board for providing a photovoltaic or solar panel, wherein the junction box is arranged on the solar module, in particular is glued to or on the solar module.

Use According to One Aspect

A further aspect of the present invention relates to the use of an inventive connection or junction box for connecting a photovoltaic or solar module with a power pick-up, wherein the electrical connection of the power pick-up with the solar module is established via the at least one contact device of the junction box.

Method According to One Aspect

One aspect of the present invention relates to the production of a connection or junction box for a circuit or conductor board, in particular a photovoltaic or solar module, with the steps:
providing at least one contact device, wherein each contact device has a contact element and a conductor terminal element,
contacting at least one connection cable with the conductor terminal element of the at least one contact device,
arranging a sealing element so that the end area of the connection cable is surrounded by the sealing element,
forming a housing device comprising a receiving device, so that the sealing element and the contact device are at least in some area(s) surrounded by the housing device,
shrinking the housing device such that a close connection with the at least one sealing element and/or the at least one contact device is established by shrinking the housing device, so that a substantially moisture-tight connection of the housing device with the sealing element and/or the at least one contact device is established.

Preferred Variants of the Method

Preferably, the at least one sealing element is a flexible sealing element, and the housing device is a substantially rigid housing device.

Preferably, the method for producing the junction box comprises the further steps:
arranging at least one bypass diode on the at least one contact device;
arranging a sealing element so that the at least one bypass diode is surrounded by the sealing element.

Advantageously, thereby, the bypass diode is enclosed by the sealing element in a moisture-tight manner.

Preferably, at least two contact devices are provided, and the at least two contact devices are mechanically and/or electrically connected with each other by means of the bypass diode.

Preferably, before the arrangement of the at least one bypass diode, the at least two contact devices are in one piece, wherein the individual contact devices are produced by separating or singularizing after the arrangement of the bypass diode.

Preferably, the contact device or a short-circuit area of the contact device is provided as an integral piece before the connection with at least one bypass diode. After the connection of the bypass diode with the contact device or the short-circuit area of the contact device, the connection of the contact elements of the contact device is interrupted or the contact elements are separated from each other. The interruption or separation preferably takes place at a predetermined breaking point of the contact device. Alternatively, the connection between the contact elements of the contact device can be interrupted after the formation of the sealing element or the formation of the housing device. Preferably, the predetermined breaking point is not comprised or surrounded by the sealing element in this case. After the separation or after the interruption, the contact elements are electrically and mechanically connected by means of the bypass diode.

In other words, after the production of the junction box, the contact device is present in at least two parts, wherein the at least two parts are connected electrically, preferably also mechanically, by means of at least one bypass diode. In particular, the short-circuit areas are connected electrically and mechanically by means of the bypass diode. After the separation, the contact device thus comprises two short-circuit areas, two contact elements and two conductor terminal elements, which are mutually connected by means of the bypass diode.

Preferably, the sealing element is applied substantially in liquid form, wherein the method comprises the further step: cooling and/or hardening the sealing element.

Further preferably, due to the cooling and/or hardening of the sealing element, the sealing element may shrink and create a close connection with the end area of the at least one connection cable and/or the at least one contact device. In particular, a moisture-tight connection between the sealing element and the end area of the cable can be established in thereby.

Preferably, the method comprises the step: providing at least one housing lid designed to close an opening of the receiving device in a moisture-tight manner.

Providing the housing lid includes in particular arranging the housing lid on the opening of the receiving device, particularly preferably arranging the housing lid on the opening of the receiving device in a moisture-tight manner.

Forming the housing device includes that a material of the housing device is arranged or deposited, in particular sprayed, on or around the sealing element, the end area of the connection cable and the contact device substantially in liquid form.

Method According to One Aspect

A further aspect of the present invention relates to a method for producing a photovoltaic or solar panel, with the steps:
providing an inventive connection or junction box;
activating an adhesive means and/or sealing means on the junction box and/or on the circuit or conductor board;
arranging the junction box on a face of the conductor board such that at least one electrical terminal element of the conductor board is inserted into the receiving device through a terminal insertion opening and that the opening on the conductor board side is closed in a substantially moisture-tight manner;
arranging at least one fixing means so that the contact element is fixed to or on the at least one electrical terminal element of the conductor board;
arranging a housing lid or cover on the junction box such that an assembly opening of the receiving device is closed by means of the housing lid in a substantially moisture-tight manner.

Preferred Variants of the Method

Preferably, the at least one electrical terminal element of the conductor board is inserted into the receiving device substantially free of force. That means, the electrical terminal element does not have to overcome a mechanical resistance, e.g. friction on the receiving device, during the insertion, so that no mechanical stress or deformation occurs at or on the electrical terminal element.

Preferably, fixation of the contact element to or on the at least one electrical terminal element of the conductor board takes place by closing the housing lid by means of at least one fixing means arranged on the housing lid. Optionally, the electrical contacting between the electrical terminal element of the conductor board and the contact element may take place by means of the fixing means as well.

Preferably, the at least one contact device can contact the contact element during arrangement of the junction box. Further preferably, the arrangement of the fixing means and the arrangement of the housing lid can be carried out in one step, namely in particular when the fixing means and the housing lid are connected with each other during arrangement.

The invention is not limited to the above-described aspects and embodiments and variants. Instead, individual elements of the aspects and/or embodiments and/or variants may be combined with each other in an arbitrary manner separately from the corresponding aspect or the corresponding embodiment or the corresponding variant, and in particular thus form new embodiments and/or variants. In other words, the above explanations regarding the individual features of the junction box analogously apply to the use(es) and the methods, and vice versa.

### DESCRIPTION OF FIGURES

Preferred embodiments of the present invention will exemplarily be described in the following on the basis of the accompanying drawings, wherein individual features can be arbitrarily combined separately from each other to form new embodiments. The figures show:

FIG. 1 an exploded view of a solar panel with a junction box;

FIG. 2 a further exploded view of the solar panel;

FIG. 3 a perspective view of the housing lid, and

FIG. 4 a sectional view of a solar panel with a junction box.

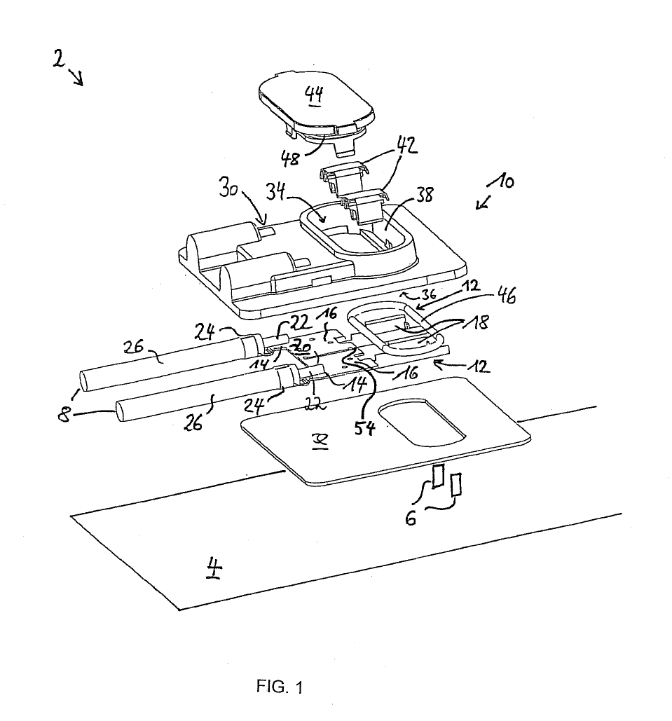

FIG. 1 shows an exploded view of a photovoltaic or solar panel 2. The solar panel 2 comprises a plate-shaped photovoltaic or solar module 4 as a current source with two terminal elements 6 between which a voltage is applied when the solar module 4 is illuminated. In order to dissipate electrical power from the solar module 4, two connection cables 8 are electrically connected with the two terminal elements 6 by means of a connection or junction box 10 arranged on the solar module.

Here, the task of the junction box 10 is, on the one hand, to accommodate electrical components, which bridge the two terminal elements 6 or the solar module 4 if the solar module is not illuminated and thus acts as an ohmic resistance, and on the other hand, to protect the electrical contacting of the terminal elements 6 with the connection cables 8 as well as the electrical components from mechanical and chemical influences, for example by violence and corrosion. Advantageously, this is achieved in that the junction box 10 is designed in a mechanically stable and moisture-tight manner.

The contacting of a terminal element 6 with an associated connection cable 8 is obtained via a contact device 12. The contact device 12 comprises a conductor terminal element 14, a short-circuit area 16, and a contact element 18. Preferably, the short-circuit area 16 is in a one-part form before the assembly, wherein the separation of the contact devices 12, i.e. the contacts of the contact devices 12, takes place after the final assembly, preferably at the predetermined breaking point 54. In FIG. 1, two contact elements 18 as well as two conductor terminal elements 14 are shown, wherein one contact element 18 is connected with one conductor terminal element 18 each. In the embodiment shown, the conductor terminal element 14 has a soldering spot at which an electrical conductor 22 of the connection cable 8 is mechanically connected, i.e. fixedly soldered, in order to establish the electrical contact between the connection cable 8 and the contact device 12. This applies analogously to both cables 8 and to both conductors 22. Alternatively or in addition, the electrical contact could be established by clamping, crimping, or the like. Furthermore, each conductor terminal element 14 preferably has a connection cable mounting device 24, which fixes or determines the insulating sheath 26 of the corresponding connection cable 8 to prevent a mechanical stress of the connection between the electrical conductor 22 and the conductor terminal element 14, in particular by tensile forces. In this embodiment, each insulating sheath 26 is fixed to the conductor terminal element by two metal strips 24 as the preferred connection cable mounting device 24.

The short-circuit area 16 establishes an electrical contact with further electrical components not shown in FIG. 1, which establish a short circuit or a bridging between the two contact devices 12 if the solar module 4 is not or only insufficiently illuminated. This bridging may e.g. take place by means of a semiconductor diode (not shown). The semiconductor diode may also be referred to as bypass diode.

Each contact element 18 contacts an electrical terminal element 6 when the junction box 10 is mounted on the solar module 4 and the junction box 10 or the solar panel 2 is in the operating state.

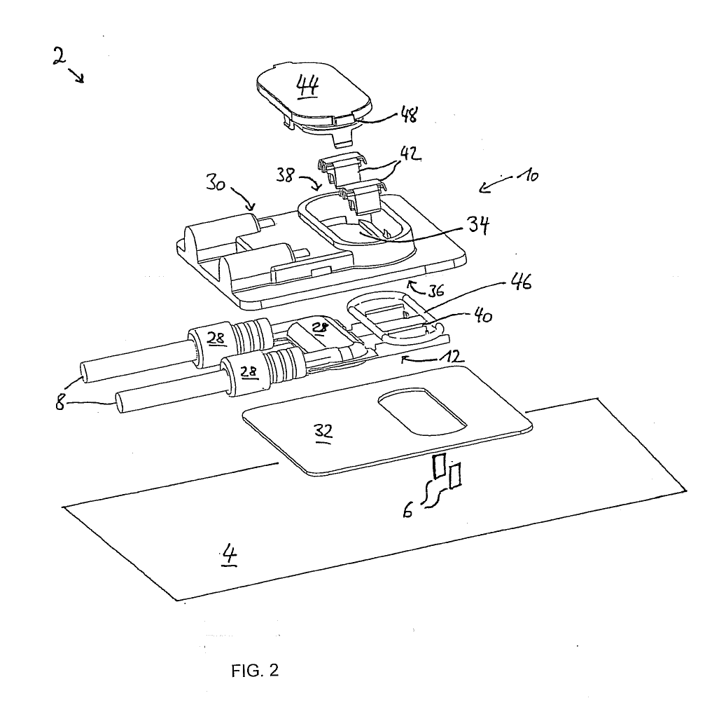

As is shown in FIG. 2, a preferably flexible sealing element 28 surrounds at least one end area of each connection cable 8. Each flexible sealing element 28 can be formed in particular by injection molding on the end area of the corresponding connection cable 8. Alternatively, a separate flexible sealing element 28 may be arranged on, e.g. by being pushed onto, the end area of the corresponding connection cable 8 in a surrounding manner. Advantageously, a flexible sealing element 28 can create a mechanical stress in the contact area between the insulating sheath 26 of the connection cable 8 and the flexible sealing element 28 by applying an external force or an external pressure. Thereby, the flexible sealing element 28 and the corresponding connection cable 8 or the insulating sheath 26 thereof are pressed together, so that substantially no gap is present between the insulating sheath 26 and the flexible sealing element 28, in which or through which moisture can migrate. Thus, i.e. due to the injection molding of the sealing element 28 on the insulating sheath 26 of the corresponding cable 8 or by application of the external force or the external pressure, a moisture-tight connection between the sealing element 28 and the insulating sheath 26 of the corresponding cable 8 is established.

Surrounding the contact device 12 and the preferably flexible sealing element 28 at least in some area(s) is formed an in particular substantially rigid housing device 30, for example by molding the housing device 30 in an injection mold, into which the contact device 12 and the flexible sealing element 28 arranged thereon are introduced. It goes without saying that the sealing element does not necessarily have to be more flexible than the housing device. The sealing element and the housing device may be equally flexible or rigid, or the sealing element may optionally be more rigid than the housing device.

In the preferred embodiment shown, the rigid housing device 30 has a substantially planar side designed to be arranged on the conductor board 4 by means of a planar adhesive means 32 in a moisture-tight manner. This adhesive means may e.g. be a double-sided adhesive tape. Furthermore, the rigid housing device 30 has a receiving device 34 with at least two openings, namely an opening or terminal insertion opening 36 on the conductor board side and an opening or assembly opening 38 opposite the conductor board. Here, the contact element 18 is arranged in the receiving device 34, so that it is contactable in the receiving device 34 by one of the electrical terminal elements 6 of the conductor board 4.

For contacting, an electrical terminal element 6 is inserted into the receiving device 34 through the terminal insertion opening 36. Preferably, the contact element 18 has a contact element back 40, so that the inserted electrical terminal element 6 can be bent over in an end area on this contact element back 40 in particular by approx. 180 degrees. A fixing element 42 is designed to be arranged on the contact element 18 or to be pushed onto it, so that the electrical terminal element 6 (bent over on the contact element back 40) is fixed and electrically contacted on the contact element 18 of the contact device 12.

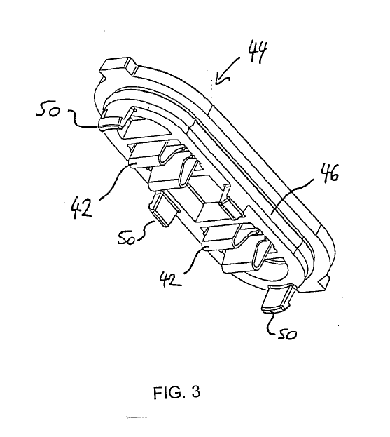

The assembly opening 38 can be closed by a housing lid or cover 44, shown in detail in FIG. 3; in a substantially moisture-tight manner. In order to increase the moisture tightness, the housing lid 44 has a housing lid sealing element 46, which is preferably arranged in a groove 48 of the housing lid 44. In order to fix the housing lid 44 after closing, the housing lid 44 comprises at least one locking element 50. In particular, the locking element 50 can be locked with the receiving device 34 by closing the housing lid 44 such that the locking is non-releasable without at least partially destroying the housing lid 44 and/or the housing device 30.

At least one fixing element 42 is arranged on the housing lid 44 in a releasable or non-releasable manner. The arrangement may take place by gluing, melting, screwing, molding, plugging, clamping, or the like. In particular, the at least one fixing element 42 may be formed in one piece with the housing lid 44. Preferably, the fixing element 42 and the housing lid 44 are made of plastic or plastics then.

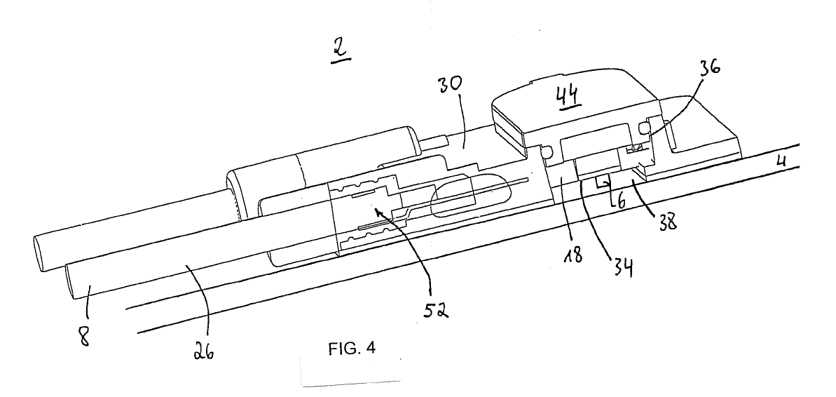

FIG. 4 shows a sectional view of a junction box 10 on a conductor board 4, wherein the receiving device 34 is closed in FIG. 4. In particular, the opening 36 on the conductor board side is closed in a moisture-tight manner by means of the conductor board 4, so that through the opening 36 on the conductor board side, no moisture, in particular liquid, can enter the receiving device 34 through the opening 36 on the conductor board side.

Likewise, the assembly opening 38 is closed in a moisture-tight manner by means of the housing lid, in particular by means of the O ring 46, so that substantially no moisture, in particular liquid, can enter the receiving device 34 through the assembly opening 38. Thus, the contact elements 18 and the electrical terminal elements 6 are substantially protected from moisture. Furthermore, the insulating sheath 26 of each cable 8 is connected with the corresponding flexible sealing element 28 in a moisture-tight manner, and each flexible sealing element 28 is connected with the housing device 30 in a moisture-tight manner. Thus, substantially no moisture, in particular no liquid, can enter the interior of the junction box in particular through cable leadthrough openings 52 in the housing device 30. Since the housing device 30 preferably has no further openings, the interior of the housing device 30 is thus sealed from the surrounding in a substantially moisture-tight manner.

The present invention is not limited to the above-described exemplary embodiments. Instead, individual elements and/or features of each described aspect and/or of each described embodiment may be combined with individual elements and/or features of the further aspects and/or further embodiments in an arbitrary manner and thus form further aspects and/or embodiments. For example, two electrical connection cables 8 with one conductor 22 each are shown in the figures. Several electrical connection cables, for example 4, 6, 8, etc., can be inserted into the junction box 2 through a corresponding number of cable leadthrough openings 52. It is also possible that several electrical connection cables 8 are inserted into the junction box through a common cable leadthrough opening 52. It is also possible that merely one electrical connection cable 8 is used, which comprises two or more electrical conductors 22.

Likewise, two or more receiving devices 34 may be present, and each of the receiving devices 34 may have an opening 36 on the conductor board side and an assembly opening 38.

Furthermore, it is not necessary that the opening(s) 36 on the conductor board side(s) and the assembly opening(s) 38 are opposite to each other. The assembly opening(s) 38 may also be arranged on a front face and/or a side face of the junction box 2.

### LIST OF REFERENCE NUMERALS

2 solar panel
4 conductor board or solar module
6 electrical terminal element of the conductor board
8 connection cable
10 junction box
12 contact device
14 conductor terminal element
16 short-circuit area
18 contact element
20 soldering spot
22 electrical conductor of the connection cable 8
24 connection cable mounting device
26 insulating sheath
28 flexible sealing element
30 housing device
32 adhesive means
34 receiving device
36 terminal insertion opening
38 assembly opening
40 contact element back
42 fixing element
44 housing lid
46 housing lid sealing element
48 groove
50 locking element
52 cable leadthrough
54 predetermined breaking point

1. A junction box for a conductor board in particular for a solar module, comprising:
at least one contact device with a conductor terminal element and a contact element,
at least one connection cable with at least one electrical conductor, wherein the electrical conductor contacts the conductor terminal element of the at least one contact device,
at least one sealing element surrounding an end area of the connection cable, so that the end area is substantially moisture-tight,
a housing device, wherein
the housing device is designed to be arranged on the conductor board,
the housing device surrounds the at least one sealing element at least in a contact area, and in the contact area, the housing device is closely connected with the sealing element such that the contact area is substantially moisture-tight, and wherein
the housing device has at least one receiving device with at least two openings, wherein in the receiving device, the contact element is arranged such that it is contactable by an electrical terminal element of the conductor board and is fixable on the electrical terminal element by means of at least one fixing element,
at least one housing lid designed to close at least one opening of the receiving device in a substantially moisture-tight manner.

2. The junction box according to claim 1, wherein the at least one sealing element is a flexible sealing element, and the housing device is a substantially rigid housing device.

3. The junction box according to claim 1, with at least two contact devices with one short-circuit area each, wherein the short-circuit

4. The junction box according to claim 1, wherein the sealing element is applied to the connection cable, the conductor terminal element, the short-circuit area and the bypass diode substantially in liquid form, and a close connection with them is created by cooling and/or hardening of the sealing element.

5. The junction box according to claim 4, wherein the sealing element is at least partly molten together with the insulating sheath of the connection cable.

6. The junction box according to claim 5, wherein the area of the sealing element molten together with the insulating sheath of the connection cable projects from the housing device at least in some area(s), so that the sealing element is an anti-kink sleeve of the connection cable.

7. The junction box according to claim 1, wherein the housing device is applied to the sealing element and the contact device substantially in liquid form, and a close connection with them is created by cooling and/or hardening of the housing device.

8. The junction box according to claim 1, wherein the housing device is in one piece.

9. The junction box according to claim 1, wherein the housing device is at least partially molten together with the sealing element.

10. The junction box according to claim 1, wherein the housing device is made of a material that is shrinkable more strongly than the material of the sealing element.

11. The junction box according to claim 1, wherein the at least one fixing element is arranged on the at least one housing lid, in particular the at least one fixing element and the at least one housing lid are in one piece.

12. The junction box according to claim 1, wherein the at least one housing lid has at least one locking element.

13. The junction box according to claim 1, wherein the at least one housing lid further comprises a housing lid sealing element.

14. The junction box according to claim 1, wherein the at least one fixing element is made of plastic or metal.

15. A use of a junction box according to claim 1 and of a solar module for providing a solar panel, wherein the junction box is arranged on the solar module, in particular is glued to the solar module.

16. A use of a junction box according to claim 1 for connecting a solar module with a power pick-up, wherein the electrical connection of the power pick-up with the solar module is established via the at least one contact device of the junction box.

17. A method for producing a junction box for a conductor board, in particular a solar module, comprising:
providing at least one contact device, wherein each contact device has a contact element and a conductor terminal element,
contacting at least one connection cable with the conductor terminal element of the at least one contact device,
arranging a sealing element so that the end area of the connection cable is surrounded by the sealing element,
forming a housing device comprising a receiving device, so that the sealing element and the contact device are at least in some area(s) surrounded by the housing device,
shrinking the housing device such that a close connection with the at least one sealing element and/or the at least one contact device is established by shrinking the housing device, so that a substantially moisture-tight connection of the housing device with the sealing element and/or the at least one contact device is established.

18. The method according to claim 17, wherein the at least one sealing element is a flexible sealing element, and the housing device is a substantially rigid housing device.

19. The method according to claim 17, further comprising:
arranging at least one bypass diode on the at least one contact device;
arranging a sealing element so that the at least one bypass diode is surrounded by the sealing element.

20. The method according to claim 17, wherein at least two contact devices are provided, and the at least two contact devices are mechanically and/or electrically connected with each other by means of the bypass diode.

21. The method according to claim 20, wherein before the arrangement of the at least one bypass diode, the at least two contact devices are in one piece, and wherein the at least two contact devices are produced by separating after the arrangement of the bypass diode.

22. The method according to claim 17, wherein the sealing element is applied substantially in liquid form, and wherein the method comprises:
cooling and hardening the sealing element.

23. The method according to claim 17, further comprising:
providing at least one housing lid designed to close an opening of the receiving device in a moisture-tight manner.

24. A method for producing a solar panel, comprising:
providing a junction box according to claim 1;
activating an adhesive means and/or sealing means on the junction box and/or on the conductor board;
arranging the junction box on a face of the conductor board such that
at least one electrical terminal element of the conductor board is inserted into the receiving device through a terminal insertion opening and;
the opening on the conductor board side is closed in a substantially moisture-tight manner;
arranging at least one fixing means so that the contact element is fixed on the at least one electrical terminal element of the conductor board;
arranging a housing lid on the junction box such that an assembly opening of the receiving device is closed by means of the housing lid in a substantially moisture-tight manner.

25. The method according to claim 24, wherein the at least one electrical terminal element of the conductor board is inserted into the receiving device substantially free of force.

26. The method according to claim 24, wherein the fixation of the contact element on the at least one electrical terminal element of the conductor board takes place by closing the housing lid by means of at least one fixing means arranged on the housing lid.
